(19) United States
(12) Patent Application Publication
(10) Pub. No.: US 2011/0079764 A1
(43) Pub. Date: Apr. 7, 2011

(54) INFORMATION RECORDING MEDIUM, MANUFACTURING METHOD THEREFOR, AND SPUTTERING TARGET

(75) Inventors: Takashi Nishihara, Osaka (JP); Rie Kojima, Osaka (JP); Noboru Yamada, Osaka (JP); Tosiyuki Matunaga, Osaka (JP)

(73) Assignee: PANASONIC CORPORATION, Kadoma-shi, Osaka (JP)

(21) Appl. No.: 12/995,616

(22) PCT Filed: Sep. 4, 2009
(86) PCT No.: PCT/JP2009/004391

§ 371 Date: Dec. 1, 2010

(30) Foreign Application Priority Data
Oct. 6, 2008 (JP) 2008-259236

(51) Int. Cl. H01L 45/00; H01L 21/62; C23C 14/14

(52) U.S. Cl. 257/3; 438/102; 204/298.13; 257/E45.002; 257/E21.52

(57) ABSTRACT

The information recording medium of the present invention includes a recording layer whose phase can be changed by application of electrical energy. The recording layer contains, as a main component, a material consisting of Ge, Te, and Sb. The material has a composition within a region defined by point (a) (35, 35, 30), point (b) (32.5, 27.5, 40), point (c) (25, 25, 50), and point (d) (27.5, 32.5, 40) and including lines from point (a) to point (b), from point (b) to point (c), from point (c) to point (d), and from point (d) to point (a), respectively, when coordinates (Ge, Te, Sb)=(x, y, z) are plotted on a triangular coordinate system shown in FIG. 1.

### TECHNICAL FIELD

The present invention relates to an information recording medium for recording, erasing, rewriting and/or reproducing information by application of electrical energy, a method of manufacturing the same, and a sputtering target.

### BACKGROUND ART

The concept of an electrical phase-change information recording medium, in which the state of a phase-change material of a recording layer is changed by Joule heat generated by application of electrical energy so as to record information on the recording layer, is shown, for example, in “Fundamentals of Amorphous Semiconductors”, edited by M. Kikuchi, (Ohmsha, 1982), Chapter 8, pages 175-178. This electrical phase-change information recording medium changes the phase-change material constituting the recording layer between a crystalline phase (low resistance) and an amorphous phase (high resistance) by Joule heat generated by application of electrical energy, and detects the difference in the electrical resistance between the crystalline phase and the amorphous phase so as to read the difference as information. When a thin film recording layer in the amorphous phase is placed between electrodes and electric current is applied gradually to the thin film recording layer, the thin film recording layer is transformed into the crystalline phase at a certain threshold current, at which the electrical resistance drops sharply. Conversely, when a high current pulse with a short duration is applied to the thin film recording layer in the crystalline phase to melt and cool it rapidly, the crystalline phase reverts back to the high resistance amorphous phase. Thus, if the recording layer formed of a phase-change material is placed between electrodes, such a unit can be used as a rewritable information recording medium. The difference in the electrical resistance between the crystalline phase and the amorphous phase can be detected easily by a common electrical means, and therefore, with the use of such a recording layer as mentioned above, a rewritable information recording medium can be obtained. The above-mentioned states of the crystalline phase and the amorphous phase are maintained even if the electrical connection is cut off. Therefore, the above information recording medium can serve as a non-volatile information recording medium to store information.

Pseudobinary GeTe—Sb₂Te₃ materials are used for the recording layers of electrical phase-change information recording media. A Ge₂Sb₂Te₅ composition, in particular, is widely used (see, for example, Patent Literature 1). These materials were developed for optical information recording media (see, for example, Patent Literature 2). These materials can be crystallized quickly on the order of several tens of nanoseconds, and a change in specific resistance between the crystalline phase and the amorphous phase is significant. Therefore, they have also been used widely in electrical information recording media.

### CITATION LIST

### Patent Literature

Patent Literature 1 JP 3454821 B2
Patent Literature 2 JP 08 (1996)-032482 B

### SUMMARY OF INVENTION

### Technical Problem

A material having a composition represented by Ge₂Sb₂Te₅, which is used widely in the recording layers of electrical phase-change information recording media, has a crystallization temperature of about 180° C. This crystallization temperature is lower than a heat treatment temperature in a semiconductor production process, and a deposition (film formation) temperature (about 250° C. or higher) by plasma chemical vapor deposition (plasma CVD), which is suitable for forming a film with good step coverage and high density. A recording layer formed of such a material is in the high resistance amorphous phase immediately after it is formed, but is transformed into the low resistance crystalline phase when it is exposed to a high temperature of 200° C. or higher in the steps following the formation of the recording layer. Accordingly, if a manufacturing method that requires the maintenance of the high temperature of 200° C. or higher is selected to form a metal film for electrical wiring or an insulating film after the formation of the recording layer, the recording layer of the electrical phase-change information recording medium thus manufactured is in the low resistance crystalline phase. In the case where cells are coplanarly arranged in a matrix form for integration, if the recording layer is in the high resistance amorphous phase, the cells can be controlled electrically independently of one another. Therefore, the recording layer does not need to be divided physically into pieces so that each of the cells has its own recording layer. That is to say, it is only necessary to form a single continuous film as a recording layer for all the cells, and therefore the step of dividing the recording layer into pieces for individual cells is not necessary. On the other hand, if the recording layer is in the low resistance crystalline phase, the cells cannot be controlled electrically independently as long as the recording layer is not divided (i.e., the recording layer is a single continuous film for all the cells). Therefore, the recording layer must be divided physically into pieces for individual cells by photolithography, or the like, and the step of dividing the recording layer into pieces for individual cells needs to be added. The flow charts of FIG. 10A and FIG. 10B show two cases of the manufacture of an electrical information recording medium: the case where the crystallization temperature of a recording layer is lower than the temperature (for example, lower than 250° C.) to which the recording layer is exposed in the steps following the formation thereof; and the case where the crystallization temperature is equal to that temperature or higher (for example, 250° C. or higher). These charts show that if a material represented by a composition formula Ge₂Sb₂Te₅ and having a crystallization temperature of about 180° C. is used for the recording layer, a new step needs to be added after the formation of the recording layer.

The present invention has been made to solve the above-mentioned conventional problems. It is an object of the present invention to obtain a recording material with an increased crystallization temperature of about 300° C. so that the recording layer can be maintained in the amorphous phase stably in its initial state, and thereby to provide an electrical phase-change information recording medium that can be produced by a simpler manufacturing method.

### Solution to Problem

The information recording medium of the present invention is an information recording medium on which information can be recorded by application of electrical energy. This information recording medium includes a recording layer whose phase can be changed by application of electrical energy. The recording layer contains, as a main component, a material consisting of Ge, Te, and Sb, and the material has a composition within a region defined by point (a) (35, 35, 30), point (b) (32.5, 27.5, 40), point (c) (25, 25, 50), and point (d) (27.5, 32.5, 40) and including lines from point (a) to point (b), from point (b) to point (c), from point (c) to point (d), and from point (d) to point (a), respectively, when coordinates (Ge, Te, Sb)=(x, y, z) are plotted on a triangular coordinate system shown in FIG. 1.

The method of manufacturing an information recording medium of the present invention includes at least a step of forming a recording layer. The recording layer formed in the step contains, as a main component, a material consisting of Ge, Te, and Sb, and the material has a composition within a region defined by point (a) (35, 35, 30), point (b) (32.5, 27.5, 40), point (c) (25, 25, 50), and point (d) (27.5, 32.5, 40) and including lines from point (a) to point (b), from point (b) to point (c), from point (c) to point (d), and from point (d) to point (a), respectively, when coordinates (Ge, Te, Sb)=(x, y, z) are plotted on a triangular coordinate system shown in FIG. 1.

The sputtering target of the present invention is a sputtering target used in a step of forming a recording layer in the method of manufacturing an information recording medium. The sputtering target has a composition represented by the following formula: (Ge_{0.5}Te_{0.5})₁₀₀₋ₐ₃Sbₐ₃ (atom %), where a3 satisfies 28≦a3≦48.

### ADVANTAGEOUS EFFECTS OF INVENTION

With the information recording medium of the present invention, since the crystallization temperature of the recording layer can be increased, the recording layer can be in the amorphous phase in its initial state. This makes it possible to produce an information recording medium by a simple manufacturing method. Furthermore, according to the information recording medium manufacturing method of the present invention, and with the sputtering target of the present invention, the information recording medium of the present invention can be manufactured easily.

### BRIEF DESCRIPTION OF DRAWINGS

FIG. 1 is a ternary diagram showing the composition range of a material used in a recording layer of an information recording medium of the present invention.

FIG. 2 is a diagram showing schematically a part of the structure of an information recording medium according to a first embodiment of the present invention and a part of the configuration of an electrical information recording/reproducing apparatus.

FIG. 3 is a diagram showing schematically a part of the structure of a high-capacity electrical information recording medium of the present invention.

FIG. 4 is a diagram showing schematically the electrical information recording medium of the present invention and a part of the configuration of a recording/reproducing system using the medium.

FIG. 5 is a diagram showing examples of recording and erasing pulse waveforms to be used for the electrical information recording medium of the present invention.

FIG. 6 is a diagram showing schematically a part of the structure of an information recording medium according to a second embodiment of the present invention and a part of the configuration of an electrical information recording/reproducing apparatus.

FIG. 7A and FIG. 7B are diagrams showing examples of recording and erasing pulse waveforms to be used for the electrical information recording medium of the present invention.

FIG. 8 is a diagram showing schematically a part of a sputtering apparatus for manufacturing the information recording medium of the present invention.

FIG. 9 is a partial sectional view showing an example of the layer structure of an optical information recording medium according to a fourth embodiment of the present invention.

FIG. 10A is a flow chart showing a part of the manufacturing process of an electrical information recording medium using a recording material having a low crystallization temperature, and FIG. 10B is a flow chart showing a part of the manufacturing process of an electrical information recording medium using a recording material having a high crystallization temperature.

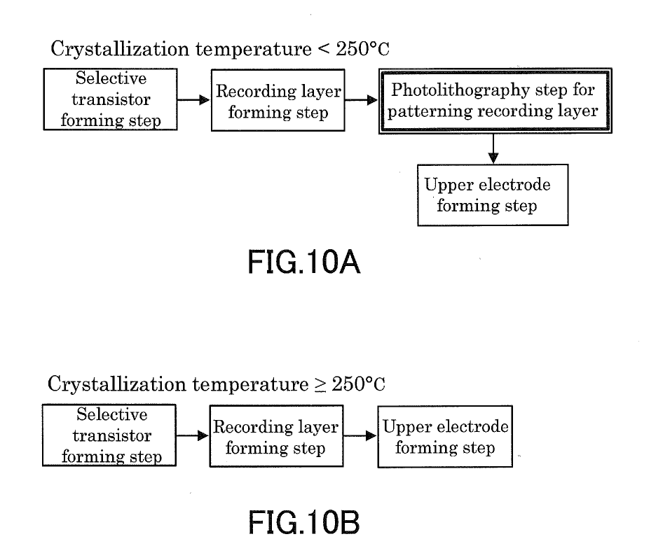

### DESCRIPTION OF EMBODIMENTS

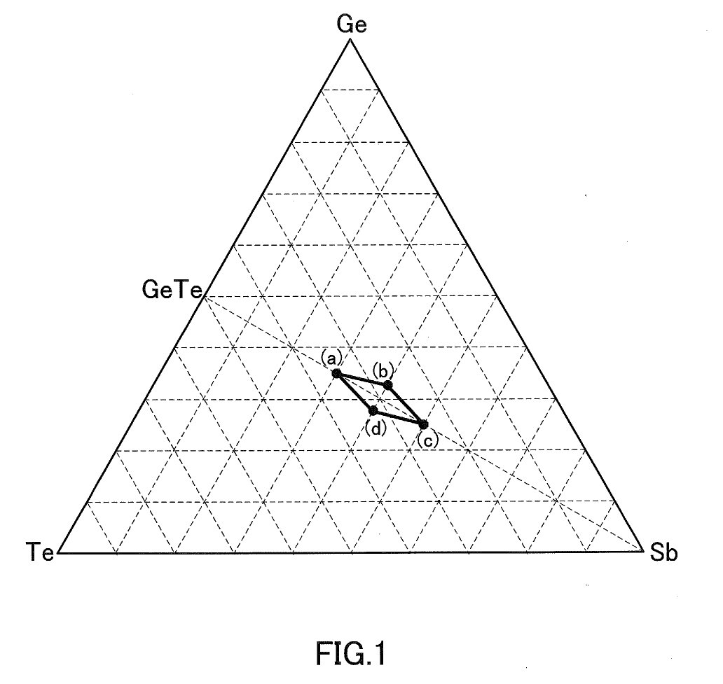

The information recording medium of the present invention is an information recording medium on which information can be recorded by application of electrical energy. This information recording medium includes a recording layer whose phase can be changed by application of electrical energy. The recording layer contains, as a main component, a material consisting of Ge, Te, and Sb, and the material has a composition within a region defined by point (a) (35, 35, 30), point (b) (32.5, 27.5, 40), point (c) (25, 25, 50), and point (d) (27.5, 32.5, 40) and including lines from point (a) to point (b), from point (b) to point (c), from point (c) to point (d), and from point (d) to point (a), respectively, when coordinates (Ge, Te, Sb)=(x, y, z) are plotted on a triangular coordinate system shown in FIG. 1. Hereinafter, in this description, the material may sometimes be referred to as a “material X”.

The recording layer of the present invention has only to contain the material X as a main component, and it may contain a trace amount of other elements as impurities, such as C, N, O, Al, Si, Cu, Zn, Ag, Ga, and In, as long as the advantageous effects of the present invention can be obtained. The recording layer can further contain additive elements to be described later in order to adjust the crystallization rate, etc. The recording layer may be formed only of the material X.

In this description, “the recording layer contains, as a main component, the material X consisting of Ge, Te, and Sb” means that when the sum total of all the atoms contained in the recording layer is taken as 100 atom %, the sum total of all the atoms contained in the material X is at least 95 atom %, preferably at least 98 atom %.

In the information recording medium of the present invention, the material X may have a composition represented by the following formula:

(Ge_{0.5}Te_{0.5})₁₀₀₋ₐ₁Sbₐ₁(atom %) (1)

where a1 satisfies 30≦a1≦50. The recording layer containing such a material can have a further increased crystallization temperature.

In the information recording medium of the present invention, a part of Sb in the material X may be substituted by M1, where M1 is at least one element selected from Bi and In, and a M1 content in the material X may be 5 atom % or less of the total material X. The crystallization rate of the recording layer can be adjusted by substituting a part of Sb by M1. In this description, “the M1 content in the material X is 5 atom % or less of the total material X” means that when the sum total of all the atoms contained in the material X is taken as 100 atom %, the sum total of all the M1 atoms contained in the material X is 5 atom % or less.

In the information recording medium of the present invention, a part of Ge in the material X may be substituted by Sn, and a Sn content in the material X may be 10 atom % or less of the total material X. The crystallization rate of the recording layer can be adjusted by substituting a part of Ge by Sn. In this description, “the Sn content in the material X is 10 atom % or less of the total material X” means that when the sum total of all the atoms contained in the material X is taken as 100 atom %, the sum total of all the Sn atoms contained in the material X is 10 atom % or less.

In the information recording medium of the present invention, the recording layer further may contain at least one element (additive element) selected from Ga, Ag, Mn, Zn, C, Si, and N. The crystallization rate and the specific resistance of the recording layer can be adjusted by adding these elements thereto.

In the information recording medium of the present invention, the recording layer may have a thickness in a range of 50 nm to 300 nm. This makes it possible to change the recording layer between the crystalline phase and the amorphous phase smoothly.

The information recording medium of the present invention may include n information layers, where n is an integer of 2 or more, and at least one of the n information layers may include the above-mentioned recording layer. This makes it possible to manufacture an information recording medium provided with a plurality of information layers by a simple method. Furthermore, it is possible to allow each of the information layers to have a recording layer with a crystallization temperature that is significantly different from other recording layers, and thus to crystallize a recording layer with a low crystallization temperature selectively. The selective crystallization of the recording layer makes it possible to bring any one of the recording layers into the crystallization state by an easier operation (without the need for a complicated erasing waveform).

The information recording medium of the present invention further may include: an interface layer disposed in contact with at least one surface of the recording layer; and an electrode disposed on a side opposite to the recording layer with respect to the interface layer. In this case, the interface layer can contain at least one compound selected from an oxide, a nitride, a carbide, a sulfide, and a fluoride. For example, the interface layer may contain O, at least one element selected from Zr, Hf, Y, and Si, and at least one element selected from Ga, In, and Cr. Such an interface layer has an excellent adhesion to the recording layer, and can reduce the mass transfer between the electrode and the recording layer. This makes it possible to obtain an information recording medium with less malfunction.

In the information recording medium of the present invention, the interface layer may have a thickness in a range of 1 nm to 5 nm. This makes it possible to achieve both the adhesion between the recording layer and the interface layer and the electrical connection between the recording layer and the interface layer.

Next, a method of manufacturing the information recording medium of the present invention will be described. The method of manufacturing an information recording medium of the present invention includes at least a step of forming a recording layer. The recording layer formed in the step contains, as a main component, a material X consisting of Ge, Te, and Sb, and the material X has a composition within a region defined by point (a) (35, 35, 30), point (b) (32.5, 27.5, 40), point (c) (25, 25, 50), and point (d) (27.5, 32.5, 40) and including lines from point (a) to point (b), from point (b) to point (c), from point (c) to point (d), and from point (d) to point (a), respectively, when coordinates (Ge, Te, Sb)=(x, y, z) are plotted on the triangular coordinate system shown in FIG. 1.

According to the information recording medium manufacturing method of the present invention, the material X contained in the recording layer formed in the step of forming the recording layer may have a composition represented by the following formula:

(Ge_{0.5}Te_{0.5})₁₀₀₋ₐ₂Sbₐ₂ (atom %) (2)

where a2 satisfies 30≦a2≦50. This makes it possible to produce an information recording medium including a recording layer with a further increased crystallization temperature.

According to the information recording medium manufacturing method of the present invention, in the material X contained in the recording layer formed in the step of forming the recording layer, a part of Sb may be substituted by M1, where M1 is at least one element selected from Bi and In, and a M1 content in the material X may be 5 atom % or less of the total material X. This makes it possible to produce an information recording medium including a recording layer with an adjusted crystallization rate.

According to the information recording medium manufacturing method of the present invention, in the material X contained in the recording layer formed in the step of forming the recording layer, a part of Ge may be substituted by Sn, and a Sn content in the material X may be 10 atom % or less of the total material X. This makes it possible to produce an information recording medium including a recording layer with an adjusted crystallization rate.

According to the information recording medium manufacturing method of the present invention, the recording layer formed in the step of forming the recording layer further may contain at least one element selected from Ga, Ag, Mn, Zn, C, Si, and N. This makes it possible to produce an information recording medium including a recording layer with adjusted crystallization temperature and specific resistance.

Hereinafter, embodiments of the present invention will be described with reference to the accompanying drawings. The following embodiments are merely examples, and the present invention is not limited to the following embodiments. In the following embodiments, the same parts are designated with the same reference numerals and overlapping descriptions may be omitted.

### First Embodiment

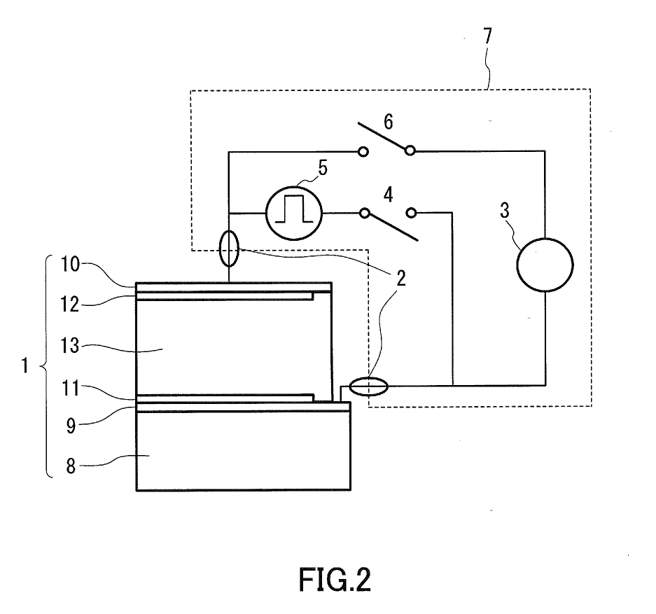

As the first embodiment, an example of the information recording medium of the present invention will be described. FIG. 2 shows an example of the structure of an electrical information recording medium 1 according to the first embodiment. The electrical information recording medium 1 is an information recording medium on and from which information can be recorded and reproduced by application of electrical energy (electric current, in particular).

The electrical information recording medium 1 has a structure in which a lower electrode 9, a first interface layer 11, a recording layer 13, a second interface layer 12, and an upper electrode 10 are stacked in this order on a substrate 8. The lower electrode 9 and the upper electrode 10 are provided to apply electric current to the recording layer 13. The first interface layer 11 and the second interface layer 12 have a function of preventing mass transfer from occurring between the recording layer 13 and the lower electrode 9 and between the recording layer 13 and the upper electrode 10, respectively, due to repeated recording. The first interface layer 11 and the second interface layer 12 also have a function of adjusting the crystallization ability of the recording layer 13, that is, promoting or suppressing the crystallization thereof. Furthermore, since the first interface layer 11 and the second interface layer 12 are formed of a material having excellent adhesion to the recording layer 13, malfunction is reduced and thus reliability can be ensured. The first interface layer 11 and the second interface layer 12 also have a function of generating heat more effectively by application of electric current in order to raise the temperature of the recording layer 13 efficiently. Hereinafter, each component will be described specifically.

As the substrate 8, a resin substrate such as polycarbonate, a glass substrate, a ceramic substrate such as Al₂O₃, a semiconductor substrate such as Si, or a metal substrate such as Cu can be used. The case where a Si substrate is used as the substrate is described below.

As a material for the first interface layer 11 and the second interface layer 12, for example, one or more oxides selected from TiO₂, ZrO₂, Hf₀₂, ZnO, Nb₂O₅, Ta₂O₅, SiO₂, SnO₂, Al₂O₃, Bi₂O₃, Cr₂O₃, Ga₂O₃, In₂O₃, Sc₂O₃, Y₂O₃, La₂O₃, Gd₂O₃, Dy₂O₃, Yb₂O₃, CaO, MgO, CeO₂, TeO₂, and the like can be used. Alternatively, one or more nitrides selected from C—N, Ti—N, Zr—N, Nb—N, Ta—N, Si—N, Ge—N, Cr—N, Al—N, Ge—Si—N, Ge—Cr—N, and the like can be used as well. Alternatively, a sulfide such as ZnS, a carbide such as SiC, a fluoride such as LaF₃ or CeF₃, or C also can be used as material for the first interface layer 11 and the second interface layer 12. Furthermore, a mixture containing one or more materials selected from the above-mentioned materials also can be used to form the first interface layer 11 and the second interface layer 12. Among these materials, materials containing Cr and O are particularly preferable because they promote the crystallization of the recording layer 13 further. Among such materials, an oxide in which Cr and O form Cr₂O₃ is a preferable material. This is because Cr₂O₃ is a material having good adhesion to the recording layer 13.

As a material for the first interface layer 11 and the second interface layer 12, a material particularly containing In and O also can be used. Among such materials, an oxide in which In and O form In₂O₃ is a preferable material. This is because In₂O₃ is a material having good adhesion to the recording layer 13.

As a material for the first interface layer 11 and the second interface layer 12, a material particularly containing Ga and O also can be used. Among such materials, an oxide in which Ga and O form Ga₂O₃ is a preferable material. This is because Ga₂O₃ is a material having good adhesion to the recording layer 13.

Furthermore, the first interface layer 11 and the second interface layer 12 further may contain at least one element selected from Zr, Hf, and Y, in addition to Cr and O, Ga and O, and/or In and O, and more preferably, the element is contained as an oxide. ZrO₂ and HfO₂ are transparent materials each having a high melting point of approximately 2700° C. to 2800° C. and a low thermal conductivity among oxides. Therefore, these materials improve the repeated rewriting performance of the information recording medium. Y₂O₃ is a transparent material and has a function of stabilizing ZrO₂ and HfO₂. When a mixture of any one or more of these three types of oxides, and Cr and O, Ga and O, and/or In and O is used for the first interface layer 11 and the second interface layer 12, either if the first interface layer 11 and the second interface layer 12 are formed partially or entirely in contact with the recording layer 13, the resulting information recording medium 1 has excellent repeated rewriting performance and thus is highly reliable.

It is preferable that the total content of Cr₂O₃, Ga₂O₃, and In₂O₃ in each of the first interface layer 11 and the second interface layer 12 be at least 10 mol % in order to ensure the adhesion to the recording layer 13.

A material further containing Si in addition to Cr, Ga, In, Zr, Hf, Y, and/or O may be used for the first interface layer 11 and the second interface layer 12. The first interface layer 11 and the second interface layer 12 containing Si, for example, in the form of SiO₂, are less crystallizable even if they are subjected to heat generated during recording, and therefore the resulting information recording medium 1 has excellent repeated rewriting performance. In order to obtain this effect sufficiently, it is preferable that the content of SiO₂ in each of the first interface layer 11 and the second interface layer 12 be at least 5 mol %. On the other hand, in order to ensure the adhesion to the recording layer 13, it is preferable that the content of SiO₂ in each of the first interface layer 11 and the second interface layer 12 be 50 mol % or less. More preferably, the content of SiO₂ is in the range of at least 10 mol % but not more than 40 mol %.

For the reasons mentioned above, it is preferable that the first interface layer 11 and the second interface layer 12 each contain O, at least one element selected from Zr, Hf, Y, and Si, and at least one element selected from Ga, In, and Cr.

In order to reduce the mass transfer and to ensure the electrical connection with the recording layer 13, it is preferable that the first interface layer 11 and the second interface layer 12 have a thickness in the range of 1 nm to 5 nm. More preferably, the thickness is in the range of 2 nm to 4 nm.

The first interface layer 11 and the second interface layer 12 can be formed by sputtering a sputtering target made of a compound constituting the first interface layer 11 and the second interface layer 12, as a material thereof, by using an RF power supply, in a rare gas atmosphere or in a mixed gas atmosphere of a rare gas and a reactive gas (O₂ gas, in particular). In order to increase the deposition rate, a minute amount of conductive material may be added to the material constituting the first interface layer 11 and the second interface layer 12. In this case, it is also possible to use a DC power supply or a pulse DC power supply to sputter the sputtering target with conductivity. Furthermore, the first interface layer 11 and the second interface layer 12 also can be formed by reactive sputtering of a sputtering target made of a metal constituting the first interface layer 11 and the second interface layer 12 by using a DC power supply, a pulse DC power supply, or an RF power supply in a mixed gas atmosphere of a rare gas and a reactive gas. Alternatively, the first interface layer 11 and the second interface layer 12 also can be formed by sputtering targets, each made of a single compound, simultaneously by using a plurality of power supplies. Furthermore, the first interface layer 11 and the second interface layer 12 also can be formed by sputtering binary sputtering targets, ternary sputtering targets, etc., each made of a mixture of at least two compounds, simultaneously by using a plurality of power supplies. When any of these sputtering targets are used, sputtering can be performed in a rare gas atmosphere or a mixed gas atmosphere of a rare gas and a reactive gas (O₂ gas, in particular). The first interface layer 11 and the second interface layer 12 also can be formed by a method such as vacuum deposition, ion plating, CVD (including plasma CVD), MBE, or the like.

The recording layer 13 is made of a material whose phase is changed reversibly between the crystalline phase and the amorphous phase by Joule heat generated by application of electric current, and utilizes a phenomenon, in which the resistivity changes between the crystalline phase and the amorphous phase, for information recording. In the information recording medium according to the present embodiment, the recording layer 13 is formed of a material that contains, as a main component, a material X consisting of Ge, Te, and Sb, and that undergoes a reversible phase change when subjected to application of electrical energy. The material X has a composition within a region defined by point (a) (35, 35, 30), point (b) (32.5, 27.5, 40), point (c) (25, 25, 50), and point (d) (27.5, 32.5, 40) and including lines from point (a) to point (b), from point (b) to point (c), from point (c) to point (d), and from point (d) to point (a), respectively, when coordinates (Ge, Te, Sb)=(x, y, z) are plotted on the triangular coordinate system shown in FIG. 1. The recording layer 13 may be formed only of the material X.

The selection of the composition within the above range allows the crystallization temperature to be increased significantly to at least about 300° C., which enhances the stability of the amorphous phase. This high crystallization temperature of at least about 300° C. allows a heat treatment process at a high temperature of about 250° C. and a deposition (film formation) process by plasma CVD to be performed after the formation of the recording layer. The high stability of the amorphous phase reduces the likelihood of malfunction caused by unintended crystallization during the high temperature operation of the electrical information recording medium 1. Furthermore, unintended crystallization is less likely to occur also when the electrical information recording medium 1 is allowed to stand for a long time. Therefore, stored information can be read out accurately. As stated herein, the crystallization temperature of at least about 300° C. is specifically a crystallization temperature of at least 290° C. If the crystallization temperature of at least 290° C. is achieved, the recording layer can be maintained in the amorphous phase sufficiently stably.

As the material X contained in the recording layer 13, a material that has a composition represented by the following formula:

(Ge_{0.5}Te_{0.5})₁₀₀₋ₐ₁Sbₐ₁(atom %) (1)

where a1 satisfies 30≦a1≦50, and that undergoes a reversible phase change may be used. The recording layer 13 may be formed so that it contains this material as a main component, or may be formed only of this material (that is, may be formed so that the composition of the recording layer 13 is represented by the formula (1)). In this case, the crystallization rate can be increased so that the erasing performance can be improved, while the crystallization temperature is maintained at least about 300° C.

In the recording layer 13, a part of Sb in the material X may be substituted by M1, where M1 is at least one element selected from Bi and In, and a M1 content in the material X may be 5 atom % or less of the total material X. The crystallization rate can be increased by substituting Sb by a small amount of Bi. The stability of the amorphous phase can be enhanced by substituting Sb by a small amount of In.

In the recording layer 13, a part of Ge in the material X may be substituted by Sn, and a Sn content in the material X may be 10 atom % or less of the total material X. The crystallization rate can be increased by substituting Ge by a small amount of Sn.

The recording layer may be formed of a material further containing at least one element selected from Ga, Ag, Mn, Zn, C, Si, and N in addition to the material X. In this case, it is preferable that the total content of Ga, Ag, Mn, Zn, C, Si, and N added be 10 atom % or less of the recording layer 13 so that the reversible phase change is not prevented. More preferably, their total content is 5 atom % or less. As stated herein, “10 (or 5) atom % or less of the recording layer 13” means that when the sum total of all the atoms contained in the recording layer 13 is taken as 100 atom %, the sum total of all the atoms of the additive elements contained in the recording layer 13 is 10 (or 5) atom % or less.

In order to raise the temperature of the recording layer 13 and cool it efficiently, it is preferable that the recording layer 13 have a thickness in the range of 50 nm to 300 nm. More preferably, the thickness is in the range of 100 nm to 250 nm.

The recording layer 13 can be formed, for example, by sputtering a sputtering target containing at least Ge, Te, and Sb by using one power supply. Specifically, the recording layer 13 can be formed by sputtering, by using one power supply, a sputtering target whose composition is adjusted so that the recording layer 13 to be formed has a composition containing the material X as a main component or a composition consisting of the material X.

Alternatively, the recording layer 13 also can be formed by sputtering, by using one power supply, a sputtering target that is modified from the sputtering target mentioned above by substituting a part of Sb by M1, where M1 is at least one element selected from Bi and In, and that is selected so that the M1 content in the material X as the main component of the recording layer 13 is 5 atom % or less of the total material X. Furthermore, the recording layer 13 also can be formed by sputtering, by using one power supply, a sputtering target that is modified from the sputtering target mentioned above by substituting a part of Ge by Sn and that is selected so that the Sn content in the material X as the main component of the recording layer 13 is 10 atom % or less of the total material X.

The recording layer 13 can also be formed by sputtering at least two sputtering targets selected from sputtering targets represented by Ge, Te, Sb, Ge—Te, Ge—Sb, and Te—Sb, simultaneously by using at least two power supplies. In this case, the composition of the recording layer to be obtained is determined according to the type and number of the sputtering targets to be used as well as the output power levels of the power supplies. Therefore, it is preferable to select these factors suitably to constitute the recording layer 13 so that the resulting recording layer 13 has a desired composition. The use of at least two types of sputtering targets is useful, for example, when it is difficult to form a sputtering target made of a mixture.

The recording layer 13 may be formed as a recording unit including at least two types of layers. In this case, each of the layers constituting the recording unit may contain the material X as a main component, or consist of the material X. Such a recording unit also can be formed by sputtering at least two sputtering targets selected from sputtering targets represented by Ge, Te, Sb, Ge—Te, Ge—Sb, and Te—Sb, sequentially and/or simultaneously by using at least two power supplies. That is, in order to form the recording unit, at least two sputtering targets may be used to perform at least two sputtering processes, or to perform simultaneous sputtering of the at least two sputtering targets.

In both cases where the recording layer 13 is formed as a recording layer having a single-layer structure and where it is formed as a recording unit having a multi-layer structure, the recording layer 13 can be formed by using a sputtering target (sputtering targets) obtained by adding at least one element selected from Ga, Ag, Mn, Zn, C, Si, and N to the above-mentioned sputtering target(s).

In both cases where the recording layer having a single-layer structure is formed and where the recording layer is formed as a recording unit, a rare gas, or a mixed gas of a rare gas and a reactive gas (for example, at least one selected from N₂ gas and O₂ gas) can be used as an atmosphere gas for sputtering. As for a power supply used for sputtering, any of a DC power supply, a pulse DC power supply, and an RF power supply can be used.

The recording layer 13 also can be formed by a method such as vacuum deposition, ion plating, CVD (including plasma CVD), MBE, or the like.

The lower electrode 9 and the upper electrode 10 can be formed by using a single metal material such as Ti, W, Al, Au, Ag, Cu, or Pt, or an alloy material containing one or more elements selected from these elements as a main component and one or more other elements added thereto as appropriate so as to, for example, improve the moisture resistance or adjust the thermal conductivity. Semiconductor materials such as Si, Ge, SiC, and the like also can be used. The lower electrode 9 and the upper electrode 10 can be formed by sputtering a metal base material or an alloy base material to be used as the material thereof in a rare gas atmosphere or a mixed gas atmosphere of a rare gas and a reactive gas (at least one selected from O₂ gas and a N₂ gas). The lower electrode 9 and the upper electrode 10 also can be formed by a method such as vacuum deposition, ion plating, CVD (including plasma CVD), MBE, or the like.

Next, the electrical information recording/reproducing apparatus 7 used for recording and reproducing information on and from the electrical information recording medium 1 will be described. The electrical information recording/reproducing apparatus 7 is connected electrically to the electrical information recording medium 1 via application units 2. With this electrical information recording/reproducing apparatus 7, a pulse power supply 5 for applying an electric current pulse to the recording layer 13 is connected between the lower electrode 9 and the upper electrode 10 via a switch 4. In order to detect the change in resistance caused by the phase change of the recording layer 13, a resistance measurement device 3 is connected between the lower electrode 9 and the upper electrode 10 via a switch 6.

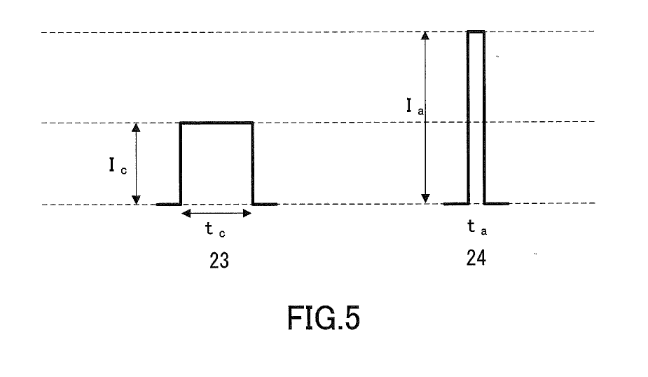

In order to change the phase of the recording layer 13 from the amorphous phase (high resistance state) to the crystalline phase (low resistance state), the switch 4 is closed (the switch 6 is opened) to apply an electric current pulse between the electrodes, so that the portion to which the electric current pulse is applied is maintained at a temperature higher than the crystallization temperature of the material constituting the recording layer 13 and lower than the melting point thereof during the crystallization process. In order to revert the crystalline phase back to the amorphous phase, a relatively higher current pulse with a shorter duration than that in the crystallization process is applied to heat the recording layer to a higher temperature than its melting point and melt it, and then the melted recording layer is cooled rapidly. The pulse power supply 5 of the electrical information recording/reproducing apparatus 7 is a power supply capable of outputting recording and erasing pulse waveforms shown in FIG. 5.

Here, the resistance value in the amorphous phase recording layer 13 and the resistance value in the crystalline phase recording layer 13 are denoted as rₐ and r_{c}, respectively. Since r_{c}<rₐ holds, two different states can be detected by measuring the resistance value between the electrodes with the resistance measurement device 3.

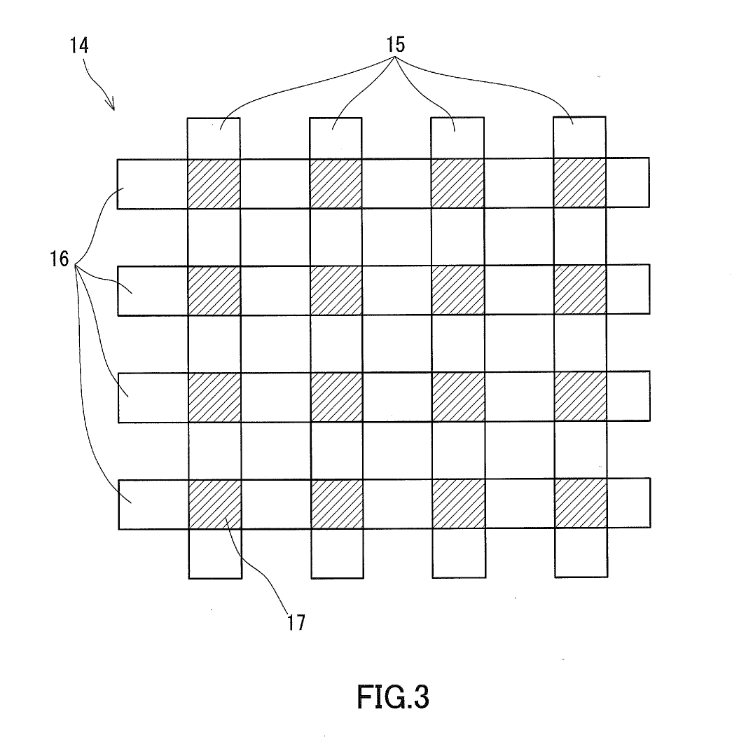

If a large number of electrical information recording media 1 are arranged in a matrix form, a high-capacity electrical information recording medium 14 as shown in FIG. 3 can be obtained. Each memory cell 17 has the same structure as that of the electrical information recording medium 1 formed in a minute region. Information is recorded on and reproduced from each of the memory cells 17 by assigning one of word lines 15 and one of bit lines 16.

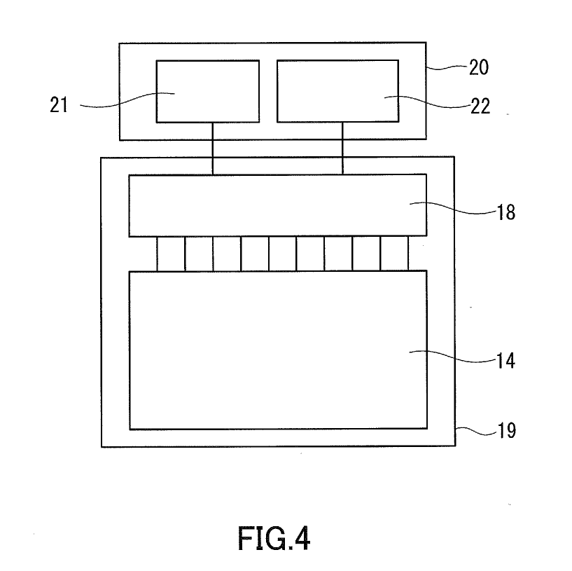

FIG. 4 shows a structural example of an information recording system in which the electrical information recording medium 14 is used. A memory unit 19 is composed of the electrical information recording medium 14 and an addressing circuit 18. The addressing circuit 18 assigns one of the ward line 15 and one of the bit lines 16 of the electrical information recording medium 14, and thereby information can be recorded on or reproduced from each of the memory cells 17.

Furthermore, if the memory unit 19 is connected electrically to an external circuit 20 composed of at least a pulse power supply 21 and a resistance measurement device 22, information can be recorded on or reproduced from the electrical information recording medium 14.

### Second Embodiment

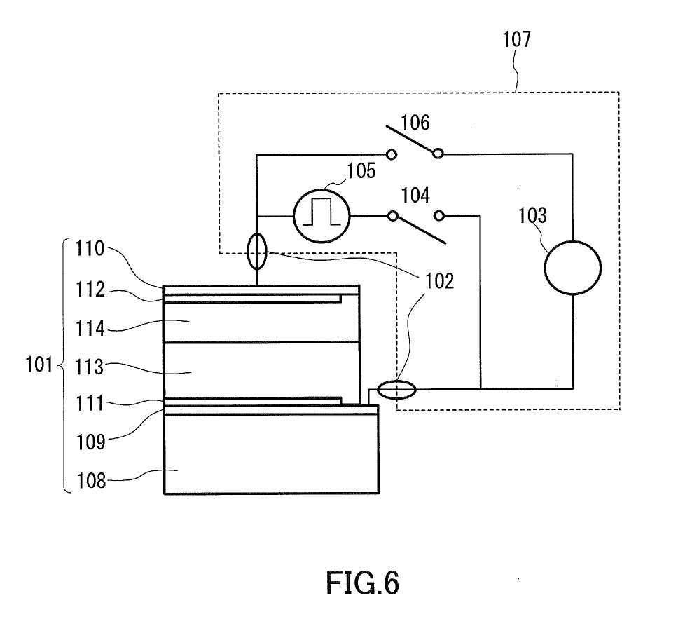

As the second embodiment, another example of the information recording medium of the present invention will be described. FIG. 6 shows an example of the structure of an electrical information recording medium 101 according to the second embodiment. The electrical information recording medium 101 is an information recording medium on and from which information can be recorded and reproduced by application of electrical energy (electric current, in particular).

The electrical information recording medium 101 has a structure in which a lower electrode 109, a first interface layer 111, a first recording layer 113, a second recording layer 114, a second interface layer 112, and an upper electrode 110 are stacked in this order on a substrate 108. That is, the electrical information recording medium 101 according to the present embodiment corresponds to an information recording medium including n information layers (in the present embodiment, n is 2), and includes two information layers, that is, an information layer composed of the first recording layer 113 and the first interface layer 111, and an information layer composed of the second recording layer 114 and the second interface layer 12.

The substrate 108 can be formed of the same material as that of the substrate 8 according to the first embodiment. The case where a Si substrate is used as the substrate 108 is described below.

The lower electrode 109, the upper electrode 110, the first interface layer 111, and the second interface layer 112 can be formed of the same materials as those of the lower electrode 9, the upper electrode 10, the first interface layer 11, and the second interface layer 12, respectively, according to the first embodiment, and can be formed by the same method as in the first embodiment.

An intermediate electrode (not shown) may be disposed between the first recording layer 113 and the second recording layer 114. The intermediate electrode is provided to reduce atomic diffusion between the first recording layer 113 and the second recording layer 114, and desirably, it is conductive. The intermediate electrode can be formed of the same material as that of the lower electrode 9 according to the first embodiment, and can be formed by the same method as for the lower electrode 9. An interface layer (not shown) may be disposed between the intermediate electrode and the first recording layer 113 and/or between the intermediate electrode and the second recording layer 114. The interface layer can be formed of the same material as that of the first interface layer 11 according to the first embodiment, and can be formed by the same method as for the first interface layer 11.

The first recording layer 113 and the second recording layer 114 are made of a material whose phase is changed reversibly between the crystalline phase and the amorphous phase by Joule heat generated by application of electric current, and utilizes a phenomenon, in which the electrical resistivity changes between the crystalline phase and the amorphous phase, for information recording. As the material for the first recording layer 113 and the second recording layer 114, the same material as that of the recording layer 13 according to the first embodiment can be used. Either one of the first recording layer 113 and the second recording layer 114 also can be formed of another material. Examples of another material include pseudobinary GeTe—Sb₂Te₃ materials, and in particular, a material having a Ge₂Sb₂Te₅ composition also can be used. The first recording layer 113 and the second recording layer 114 can be formed by the same method as for the recording layer 13 according to the first embodiment.

The electrical information recording/reproducing apparatus 107 is connected electrically to the electrical information recording medium 101 via application units 102. With this electrical information recording/reproducing apparatus 107, a pulse power supply 105 for applying an electric current pulse to the first recording layer 113 and the second recording layer 114 is connected between the lower electrode 109 and the upper electrode 110 via a switch 104. In order to detect the change in resistance caused by the phase change of the first recording layer 113 and the second recording layer 114, a resistance measuring device 103 is connected between the lower electrode 109 and the upper electrode 110 via a switch 106.

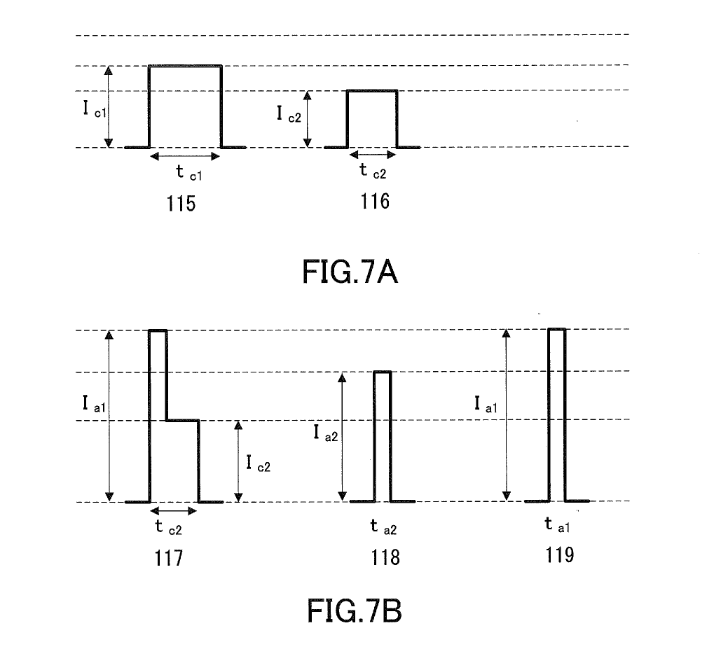

In order to change the phase of the first recording layer 113 or the second recording layer 114 from the amorphous phase (high resistance state) to the crystalline phase (low resistance state), the switch 104 is closed (the switch 106 is opened) to apply an electric current pulse between the electrodes, so that the portion to which the electric current pulse is applied is maintained at a temperature higher than the crystallization temperature of the material and lower than the melting point thereof during the crystallization process. In order to revert the crystalline phase back to the amorphous phase, a relatively higher current pulse with a shorter duration than that in the crystallization process is applied to heat it to a higher temperature than its melting point and melt it, and then the melted recording layer is cooled rapidly. The pulse power supply 105 of the electrical information recording/reproducing apparatus 107 is a power supply capable of outputting recording and erasing pulse waveforms shown in FIG. 7A and FIG. 7B.

Here, the resistance value in the amorphous phase first recording layer 113, the resistance value in the crystalline phase first recording layer 113, the resistance value in the amorphous phase second recording layer 114, and the resistance value in the crystalline phase second recording layer 114 are denoted as rₐ₁, r_{c1}, rₐ₂, and r_{c21}, respectively. Since r_{c1}≦r_{c2}<rₐ₁<r_{c1}≦r_{c2}rₐ₂<rₐ₂<rₐ₁, r_{c2}<r_{c1}<rₐ₁<rₐ₂, or r_{c2}≦r_{c1}<rₐ₂<rₐ₁ holds, four different values, rₐ₁+rₐ₂, rₐ₁+r_{c2}, rₐ₂+r_{c1}, and r_{c1}+r_{c2} can be set as the total of the resistance values in the first recording layer 113 and the second recording layer 114. Therefore, four different states, that is, binary information signals can be detected at a time by measuring the resistance value between the electrodes with the resistance measurement device 103.

If a large number of electrical information recording media 101 are arranged in a matrix form, a high-capacity electrical information recording medium 14 as shown in FIG. 3 can be obtained as in the first embodiment.

The example where two information layers each including the recording layer are stacked has been described so far. With the same concept as above, n (n is an integer of 2 or more) information layers each including a recording layer can be stacked so as to record, erase, and reproduce n-valued information signals at a time.

### Third Embodiment

As the third embodiment, an example of a sputtering target used for manufacturing the information recording medium of the present invention will be described below.

The sputtering target according to the present embodiment contains at least one element selected from Ge, Te, and Sb. Specifically, the sputtering target of the present embodiment has a composition represented by the following formula:

(Ge_{0.5}Te_{0.5})₁₀₀₋ₐ₃Sbₐ₃ (atom %) (3)

where a3 satisfies 28≦a3≦48.

In the above sputtering target, a part of Sb may be substituted by at least one element selected from Bi and In (hereinafter, a group of these elements is referred to as M1). A part of Ge may be substituted by Sn. The sputtering target further may contain at least one element selected from Ga, Ag, Mn, Zn, C, Si, and N (hereinafter, a group of these elements is referred to as M2).

With the use of any of these sputtering targets, the recording layer containing Ge—Te—Sb, Ge—Te—Sb-M1, Ge—Sn—Te—Sb, Ge—Sn—Te—Sb-M1, Ge—Te—Sb-M2, Ge—Te—Sb-M1-M2, Ge—Sn—Te—Sb-M2, or Ge—Sn—Te—Sb-M1-M2 can be formed for the information recording medium of the present invention. The use of any of these sputtering targets makes it possible to form the recording layer by introducing only a rare gas, or a rare gas and a minute amount of reactive gas. In the case of high-rate deposition (film formation), variations in the information recording medium, for example, medium-to-medium variations in resistance, and cell to cell variations in resistance in one plane, can be reduced to a low level. To perform higher-rate deposition (film formation) and reduce variations in resistance, the sputtering target according to the present embodiment preferably has high density (which indicates the filling rate of powder when the state in which the powder is filled with no gaps is defined as 100%). The density of the sputtering target preferably is at least 80%, and more preferably at least 90%.

Next, an example of the method of manufacturing the sputtering target according to the present embodiment will be described.

As an example, a manufacturing method of a sputtering target containing Ge, Te, and Sb will be described. A Ge material powder, a Te material powder, and a Sb material powder, each having a high purity and a predetermined particle size, are prepared. Then, these material powders are weighed and mixed at a predetermined mixing ratio, and the mixture is put in a hot press. The hot press is evacuated, if necessary, and the mixture of the powders is maintained at a predetermined high pressure and high temperature for a predetermined period of time. Thus the mixture is sintered. Sufficient stirring of the mixture allows the resulting sputtering target to have a uniform composition in in-plane and thickness directions. Furthermore, optimization of the conditions of pressure, temperature, and holding time enhances the filling property of the powder mixture, allowing the sputtering target with a high density to be produced. Thus, the sputtering target containing Ge, Te, and Sb at a predetermined composition ratio is obtained. After the mixture is sintered, the sputtering target thus obtained may be bonded, for example, to a copper plate with a smooth surface by a solder made of In or the like, if necessary. When thus prepared, the sputtering target can be set in the sputtering apparatus for sputtering.

Likewise, the sputtering target containing Ge, Te, Sb, Sn, M1, and M2 can be produced in the same manner as described above by preparing powders of high purity materials Ge, Te, Sb, Sn, M1, and M2, each having a predetermined particle size. Alternatively, powders of high purity materials Ge—Te and Sb-M1, each having a predetermined particle size, may be prepared. Powders of high purity materials Ge—Sn and Te—Sb, each having a predetermined particle size, may be prepared. Powders of high purity materials Ge—Sb, Te-M1, and Sn-M2, each having a predetermined particle size, may be prepared. Powders of high purity materials Ge—Sn—Te, Sb-M1-M2, Ge—Te—Sb, and Sn-M1-M2, each having a predetermined particle size, may be prepared. The sputtering target can be produced in the same manner as described above using any of the powder mixtures as mentioned above.

As a method of producing the recording layer, it is desirable to form it by sputtering using any of the above-mentioned sputtering targets. The use of sputtering has the advantage of being able to obtain good-quality thin films relatively easily because film forming apparatuses for mass production of multilayer films already have been marketed.

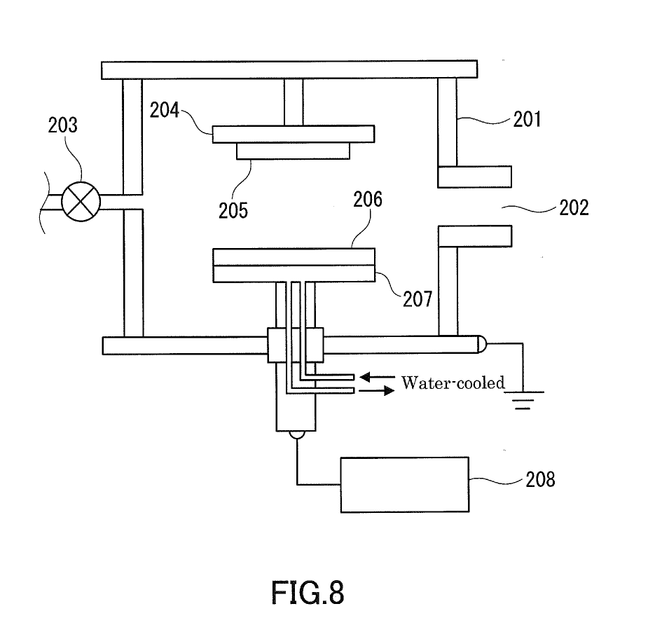

An example of a sputtering apparatus used in the present embodiment will be described below. FIG. 8 shows how films are formed using the sputtering apparatus. As shown in FIG. 8, in this sputtering apparatus, a vacuum pump (not shown) is connected to a vacuum chamber 201 through an exhaust port 202 so that a high vacuum can be maintained in the vacuum chamber 201. A gas can be supplied at a predetermined flow rate from a gas supply port 203. A substrate 205 (the substrate herein refers to a base material on which a film is to be deposited) is mounted on an anode 204. The vacuum chamber 201 and the substrate 205 are maintained positive by grounding the vacuum chamber 201. A sputtering target 206 is connected to a cathode 207, and is connected to a power supply 208 via a switch (not shown). When a predetermined voltage is applied between the anode 204 and the cathode 207, particles are ejected from the sputtering target 206, and thereby a thin film is formed on the substrate 205. It is preferable to use a sputtering apparatus provided with a permanent magnet on the rear surface of the sputtering target 206 so that plasma is concentrated more efficiently to increase the sputtering rate.

### Fourth Embodiment

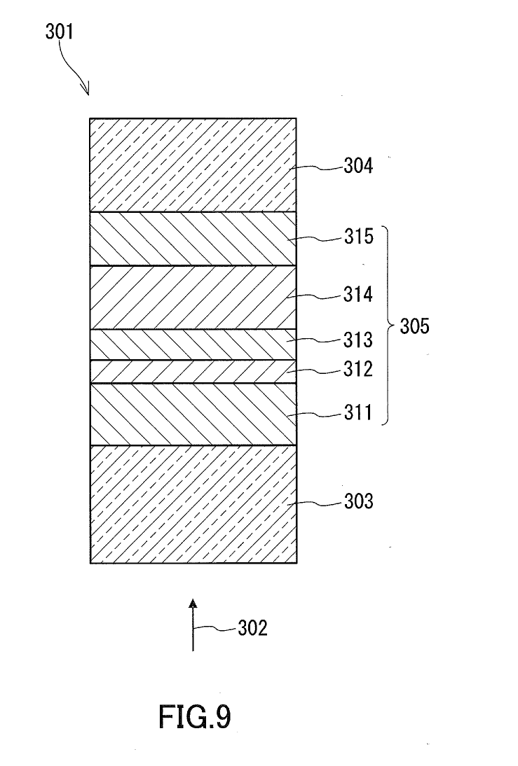

In the fourth embodiment, another example of the information recording medium of the present invention will be described. FIG. 9 shows a partial cross-sectional view of an optical information recording medium 301 according to the fourth embodiment. The optical information recording medium 301 is an optical information recording medium on and from which information can be recorded and reproduced by irradiation of a laser beam 302, that is, by an optical means.

The optical information recording medium 301 is composed of a substrate 304, and an information layer 305 and a transparent layer 303 formed on the substrate 304. The transparent layer 303 is made of a resin such as a photocurable resin (an ultraviolet curable resin, in particular) or a slow-acting thermosetting resin, a dielectric, or the like. Preferably, the transparent layer 303 has low optical absorption of the laser beam 302 to be used and has low optical birefringence in a short wavelength region. For the transparent layer 303, a disk-shaped transparent material, for example, a resin such as polycarbonate, amorphous polyolefin, or polymethylmethacrylate (PMMA), or glass. In this case, the transparent layer 303 can be laminated to a first dielectric layer 311 with a resin such as a photocurable resin (an ultraviolet curable resin, in particular) or a slow-acting thermosetting resin, an adhesive sheet, or the like.

The spot diameter of the focused laser beam 302 is determined by the wavelength λ of the laser beam 302 (i.e., a laser beam with a shorter wavelength λ can be focused on a smaller spot diameter). Therefore, it is preferable that the wavelength λ of the laser beam 302 be 450 nm or less in particular. When the wavelength λ is less than 350 nm, the optical absorption of the transparent layer 303, etc. is too high. Therefore, it is more preferable that the wavelength λ of the laser beam 302 be in the range of 350 nm to 450 nm.

The substrate 304 is a disk-shaped transparent substrate. For the substrate 304, for example, a resin such as polycarbonate, amorphous polyolefin, or PMMA, or glass can be used.

A guide groove for guiding the laser beam may be formed, if necessary, on the surface of the substrate 304 facing the information layer 305. The other surface of the substrate 304 opposite to the information layer 305 is preferably flat and smooth. As the material of the substrate 304, polycarbonate is particularly useful for its high transfer properties, suitability for mass productivity, as well as its low cost. It is preferable that the thickness of the substrate 304 be in the range of 0.5 mm to 1.2 mm so that the substrate 304 is strong enough and the information recording medium 301 has a thickness of about 1.2 mm. If the thickness of the transparent layer 303 is about 0.6 mm (the thickness at which recording/reproduction can be performed well with a numerical aperture (NA)=0.6), then it is preferable that the thickness of the substrate 304 be in the range of 5.5 mm to 6.5 mm. If the thickness of the transparent layer 303 is about 0.1 mm (the thickness at which recording/reproduction can be performed well with a numerical aperture (NA)=0.85), then it is preferable that the thickness of the substrate 304 be in the range of 1.05 mm to 1.15 mm.

The structure of the information layer 305 is described below.

The information layer 305 includes a first dielectric layer 311, a first interface layer 312, a recording layer 313, a second dielectric layer 314, and a reflective layer 315, which are disposed in this order from the incident side of the laser beam 302.

The first dielectric layer 311 is made of a dielectric material. This first dielectric layer 311 has functions of protecting the recording layer 313 from oxidation, corrosion, deformation, etc.; adjusting the optical distance so as to enhance the light absorption efficiency of the recording layer 313; and increasing the difference in the amount of reflected light between before and after recoding so as to increase the signal intensity. As the material of the first dielectric layer 311, for example, an oxide such as TiO₂, ZrO₂, HfO₂, ZnO, Nb₂O₅, Ta₂O₅, SiO₂, SnO₂, Al₂O₃, Bi₂O₃, Cr₂O₃, Ga₂O₃, In₂O₃, Sc₂O₃, Y₂O₃, La₂O₃, Gd₂O₃, Dy₂O₃, Yb₂O₃, CaO, MgO, CeO₂, TeO₂, or the like can be used. A nitride such as C—N, Ti—N, Zr—N, Nb—N, Ta—N, Si—N, Ge—N, Cr—N, Al—N, Ge—Si—N, Ge—Cr—N, or the like also can be used. A sulfide such as ZnS, a carbide such as SiC, a fluoride such as LaF₃ or CeF₃, or C also can be used. Furthermore, a mixture of the above materials also can be used. For example, ZnS—SiO₂, which is a mixture of ZnS and SiO₂, is a particularly excellent material for the first dielectric layer 311. This is because ZnS—SiO₂ is an amorphous material and has a high refractive index, a high deposition rate, good mechanical properties, and good moisture resistance.

The thickness of the first dielectric layer 311 can be determined exactly by calculations based on a matrix method so as to satisfy the conditions under which the difference in the amount of reflected light between when the recording layer 313 is in the crystalline phase and when it is in the amorphous phase is increased.

The first interface layer 312 has a function of preventing mass transfer from occurring between the first dielectric layer 311 and the recording layer 313 due to repeated recording. The first interface layer 312 also has a function of adjusting the crystallization ability of the recording layer 313, that is, promoting or suppressing the crystallization thereof. Preferably, the first interface layer 312 is formed of a material that absorbs less light, has a melting point high enough to prevent it from being melted during recording, and has good adhesion to the recording layer 313. For the first interface layer 312, the same material as that of the first interface layer 11 according to the first embodiment can be used. It is desirable that the thickness of the first interface layer 312 be in the range of 0.5 nm to 15 nm in order to prevent the difference in the amount of reflected light between before and after recording on the information layer 305 from decreasing due to light absorption in the first interface layer 312. More preferably, the thickness is in the range of 1 nm to 10 nm.

For the second dielectric layer 314, the same material as that of the first dielectric layer 311 can be used. The thickness of the second dielectric layer 314 is preferably in the range of 2 nm to 75 nm, and more preferably in the range of 2 nm to 40 nm. The selection of the thickness of the second dielectric layer 314 within this range allows the heat generated in the recording layer 313 to be diffused to the side of the reflective layer 315 effectively.

As the material of the recording layer 313, the same material as that of the recording layer 13 (see FIG. 2) in the electrical information recording medium 1 according to the first embodiment can be used, and the material also can undergo a phase change between the crystalline phase and the amorphous phase by irradiation with the laser beam 302. In order to increase the recording sensitivity of the information layer 305, the thickness of the recording layer 313 is preferably in the range of 6 nm to 15 nm. When the thickness of the recording layer 313 is large even if it is within this range, it has a significant thermal influence on the adjacent areas due to the diffusion of heat in the in-plane direction. When the recording layer 313 is thin, the reflectance of the information layer 305 is low. Therefore, it is more preferable that the thickness of the recording layer 313 be in the range of 8 nm to 13 nm. The use of the recording layer material of the present invention (for example, the material X) as the material of the recording layer 313 allows the crystallization temperature to be increased to 290° C. or higher. As a result, the long-term storage of recorded information and the durability against laser beam irradiation for reproducing information can be enhanced significantly. Furthermore, since the crystallization temperature can be increased to 290° C. or higher, an optical information recording medium having excellent durability in high temperature environments in which it is used, such as in a car, and thus having high reliability can be provided.

A second interface layer (not shown) may be disposed between the recording layer 313 and the second dielectric layer 314. Like the first interface layer 312, the second interface layer has a function of preventing mass transfer from occurring between the second dielectric layer 314 and the recording layer 313 due to repeated recording. For the second interface layer, the same material as that of the first interface layer 312 can be used. Like the first interface layer 312, the thickness of the second interface layer is desirably in the range of 0.5 nm to 15 nm, and more preferably in the range of 1 nm to 10 nm.

The reflective layer 315 has an optical function of increasing the amount of light absorbed by the recording layer 313. The reflective layer 315 also has a thermal function of diffusing heat generated in the recording layer 313 quickly so that the recording layer 313 is transformed into the amorphous state more easily. Furthermore, the reflective layer 315 also has a function of protecting the multilayer film from the surrounding environment in which it is used.

As the material of the reflective layer 315, for example, a single metal having a high thermal conductivity, such as Ag, Au, Cu, or Al, can be used. Alternatively, an alloy such as Al—Cr, Al—Ti, Al—Ni, Al—Cu, Au—Pd, Au—Cr, Ag—Cu, Ag—Pd, Ag—Pd—Cu, Ag—Pd—Ti, Ag—Ru—Au, Ag—Cu—Ni, Ag—Zn—Al, Ag—Nd—Au, Ag—Nd—Cu, Ag—Bi, Ag—Ga, Ag—Ga—In, Ag—Ga—Cu, Ag—In, Ag—In—Sn, or Cu—Si also can be used. Particularly, an Ag alloy is preferable as the material for the reflective layer 315 because it has a high thermal conductivity. The thickness of the reflective layer 315 is preferably at least 30 nm, at which its heat diffusion performance is high enough. When the reflective layer 315 has a thickness larger than 200 nm, which is within the above range, it exhibits excessively high heat diffusion performance and thereby the recording sensitivity of the information layer 305 decreases. Therefore, it is more preferable that the thickness of the reflective layer 315 be in the range of 30 nm to 200 nm.

An interface layer may be disposed between the reflective layer 315 and the second dielectric layer 314. In this case, for the interface layer, a material having a lower thermal conductivity than the materials described for the reflective layer 315 can be used. In the case where an Ag alloy is used for the reflective layer 315, Al or an Al alloy, for example, can be used for the interface layer. For the dielectric layer, an element such as Cr, Ni, Si, or C, or an oxide such as TiO₂, ZrO₂, HfO₂, ZnO, Nb₂O₅, Ta₂O₅, SiO₂, SnO₂, Al₂O₃, Bi₂O₃, Cr₂O₃, Ga₂O₃, In₂O₃, Sc₂O₃, Y₂O₃, La₂O₃, Gd₂O₃, Dy₂O₃, Yb₂O₃, CaO, MgO, CeO₂, or TeO₂ can be used. A nitride such as C—N, Ti—N, Zr—N, Nb—N, Ta—N, Si—N, Ge—N, Cr—N, Al—N, Ge—Si—N, or Ge—Cr—N also can be used. A sulfide such as ZnS, a carbide such as SiC, a fluoride such as LaF₃₀r CeF₃, or C also can be used. Furthermore, a mixture of the above materials also can be used. The thickness is preferably in the range of 3 nm to 100 nm (more preferably, in the range of 10 nm to 50 nm).

It is preferable that the reflectance R_{c}(%) of the information layer 305 obtained when the recording layer 313 is in the crystalline phase and the reflectance Rₐ (%) of the information layer 305 obtained when the recording layer 313 is in the amorphous phase satisfy the condition Rₐ<R_{c}. This allows the reflectance to be higher in the initial state in which information has not yet been recorded, thereby allowing a stable recording/reproducing operation to be performed. Furthermore, in order to increase the difference in reflectance (R_{c}−Rₐ) and to obtain good recording/reproducing characteristics, R_{c} and Rₐ preferably satisfy 0.2≦Rₐ≦10 and 12≦R_{c}≦40 respectively, and more preferably 0.2≦Rₐ≦5 and 12≦R_{c}≦30 respectively.

The example of the optical information recording medium including one information layer has been described so far. If the thicknesses of the recording layer and the reflective layer of the present invention are reduced significantly to design a translucent information layer capable of transmitting a laser beam, n information layers can be stacked to increase the recording capacity by n times.

### EXAMPLES

More specific embodiments of the present invention will be described in further detail by way of examples.

### Example 1

In Example 1, the relationship between the materials of the sputtering targets to be used to form the recording layer 13 of the electrical information recording medium 1 in FIG. 2, the first recording layer 113 and/or the second recording layer 114 of the electrical information recording medium 101 in FIG. 6, and the recording layer 313 of the optical information recording medium 301 in FIG. 9 and the compositions of the recording layers thus formed actually was examined. Specifically, a plurality of sputtering targets having different compositions were prepared, and the composition of the recording layer formed from each of the sputtering targets was measured by inductively coupled plasma (ICP) emission spectrometry.

Samples were produced in the following manner. Glass substrates (with a diameter of 120 mm and a thickness of 0.6 mm) were prepared as substrates for ICP emission spectrometry. Then, a recording layer with a thickness of 300 nm was formed on each of the glass substrates by sputtering. The sputtering target used to form the recording layer was 100 mm in diameter and 6 mm in thickness. The recording layer was formed in an Ar gas atmosphere at a pressure of 0.2 Pa at an input power of 100 W from a direct current (DC) power supply. A plurality of recording layer samples made of different materials were produced in the manner as described above.

The recording layer samples thus obtained were subjected to ICP emission spectrometry to measure the compositions thereof.

The measurement results of the composition of the sputtering target used for forming each of the recording layer samples and the composition of the resulting recording layer sample are shown below (Table 1). The compositions thus measured have an error of ±0.5 atom %.

TABLE 1

| Composition of Sputtering Target | Composition of Resulting Film |
|---|---|
| (atom %) | (atom %) |
| Ge_{40.5}Te_{40.5}Sb₁₉ | Ge_{39.5}Te_{39.5}Sb₂₁ |
| Ge₃₆Te₃₆Sb₂₈ | Ge₃₅Te₃₅Sb₃₀ |
| Ge₃₁Te₃₁Sb₃₈ | Ge₃₀Te₃₀Sb₄₀ |
| Ge₂₇Te₂₇Sb₄₆ | Ge₂₅Te₂₅Sb₅₀ |
| Ge₂₂Te₂₂Sb₅₆ | Ge₂₀Te₂₀Sb₆₀ |

These results show that it is preferable to select, as a sputtering target used for forming the recording layer, a sputtering target having a composition represented by (Ge_{0.5}Te_{0.5})₁₀₀₋ₐ₃Sbₐ₃ (atom %), where a3 satisfies 28≦a3≦48 in order to obtain the recording layer having a composition represented by (Ge_{0.5}Te_{0.5})₁₀₀₋ₐ₁Sbₐ₁(atom %), where a1 satisfies 30≦a1≦50.

The above example shows the results of the compositions on the line from GeTe point to Sb point on the triangular coordinate system of FIG. 1. However, with the use of the composition of the recording layer of the present invention, that is, a composition within a region defined by point (a) (35, 35, 30), point (b) (32.5, 27.5, 40), point (c) (25, 25, 50), and point (d) (27.5, 32.5, 40) and including lines from point (a) to point (b), from point (b) to point (c), from point (c) to point (d), and from point (d) to point (a), respectively, on the triangular coordinate system of FIG. 1, a film having a desired composition could be formed by using a sputtering target containing less Sb than that in the desired composition of the film. Therefore, the amount of Ge does not necessarily have to be the same as that of Te like the samples shown in Table 1 above.

### Example 2

In Example 2, the relationship between the compositions and thicknesses of the recording materials to be used to form the recording layer 13 of the electrical information recording medium 1 in FIG. 2, the first recording layer 113 and/or the second recording layer 114 of the electrical information recording medium 101 in FIG. 6, and the recording layer 313 of the optical information recording medium 301 in FIG. 9 and the crystallization temperatures of these recording materials was examined. Specifically, a plurality of recording layer samples having different compositions and thicknesses were prepared, and their crystallization temperatures were measured.

The samples were produced in the following manner. Quartz substrates (with a diameter of 8 mm and a thickness of 0.3 mm) were prepared as substrates for the measurement of the crystallization temperatures. Then, a recording layer was formed on each of the substrates by sputtering. The sputtering target used to form the recording layer was 100 mm in diameter and 6 mm in thickness. The recording layer was formed in an Ar gas atmosphere at a pressure of 0.2 Pa at an input power of 100 W from a direct current (DC) power supply. A plurality of recording layer samples having different compositions and thicknesses were produced in the manner as described above.

Each of the samples thus obtained was subjected to slow heating at a rate of 1° C./sec, and the change in the optical reflectance was detected with a He—Ne laser. The crystallization temperature was defined as a temperature at which the change in the optical reflectance begins.

The measurement results of the composition and thickness of each of the recording layer samples and the crystallization temperature thereof are shown below (Table 2).

TABLE 2

| | Composition of | | |
|---|---|---|---|
| Sample | Recording Layer | Thickness of | Crystallization |
| No. | (atom %) | Recording Layer | Temperature |
| 2-1 | Ge₄₅Te₄₅Sb₁₀ | 200 nm | 265° C. |
| 2-2 | Ge_{39.5}Te_{39.5}Sb₂₁ | 200 nm | 285° C. |
| 2-3 | Ge₃₅Te₃₅Sb₃₀ | 200 nm | 300° C. |
| 2-4 | Ge₃₀Te₃₀Sb₄₀ | 200 nm | 315° C. |
| 2-5 | Ge₂₅Te₂₅Sb₅₀ | 200 nm | 305° C. |
| 2-6 | Ge₂₀Te₂₀Sb₆₀ | 200 nm | 285° C. |
| 2-7 | Ge₁₅Te₁₅Sb₇₀ | 200 nm | 265° C. |
| 2-8 | Ge₃₅Te₂₅Sb₄₀ | 200 nm | 282° C. |
| 2-9 | Ge_{32.5}Te_{27.5}Sb₄₀ | 200 nm | 307° C. |
| 2-10 | Ge_{27.5}Te_{32.5}Sb₄₀ | 200 nm | 303° C. |
| 2-11 | Ge₂₅Te₃₅Sb₄₀ | 200 nm | 280° C. |
| 2-12 | Ge_{22.2}Te_{55.6}Sb_{22.2} | 200 nm | 180° C. |
| 2-13 | Ge₃₀Te₃₀Sb₃₈Bi₂ | 200 nm | 305° C. |
| 2-14 | Ge₃₀Te₃₀Sb₃₅Bi₅ | 200 nm | 290° C. |
| 2-15 | Ge₃₀Te₃₀Sb₃₂Bi₈ | 200 nm | 275° C. |
| 2-16 | Ge₃₀Te₃₀Sb₃₈In₂ | 200 nm | 320° C. |
| 2-17 | Ge₃₀Te₃₀Sb₃₅In₅ | 200 nm | 325° C. |
| 2-18 | Ge₂₅Sn₅Te₃₀Sb₄₀ | 200 nm | 308° C. |
| 2-19 | Ge₂₀Sn₁₀Te₃₀Sb₄₀ | 200 nm | 300° C. |
| 2-20 | Ge₁₅Sn₁₅Te₃₀Sb₄₀ | 200 nm | 285° C. |
| 2-21 | Ge_{28.5}Te_{28.5}Sb₃₈Ga₅ | 200 nm | 310° C. |
| 2-22 | Ge₂₇Te₂₇Sb₃₆Ga₁₀ | 200 nm | 305° C. |
| 2-23 | Ge_{28.5}Te_{28.5}Sb₃₈Ag₅ | 200 nm | 310° C. |
| 2-24 | Ge_{28.5}Te_{28.5}Sb₃₈Mn₅ | 200 nm | 320° C. |
| 2-25 | Ge_{28.5}Te_{28.5}Sb₃₈Zn₅ | 200 nm | 305° C. |
| 2-26 | Ge_{28.5}Te_{28.5}Sb₃₈C₅ | 200 nm | 330° C. |
| 2-27 | Ge_{28.5}Te_{28.5}Sb₃₈Si₅ | 200 nm | 320° C. |
| 2-28 | Ge_{28.5}Te_{28.5}Sb₃₈N₅ | 200 nm | 325° C. |
| 2-29 | Ge₂₅Sn₅Te₃₀Sb₃₈Bi₂ | 200 nm | 298° C. |
| 2-30 | Ge₂₅Sn₅Te₃₀Sb₃₈In₂ | 200 nm | 313° C. |
| 2-31 | Ge_{28.5}Te_{28.5}Sb₃₆Bi₂C₅ | 200 nm | 320° C. |
| 2-32 | Ge₂₄Sn₅Te₂₈Sb₃₈C₅ | 200 nm | 322° C. |
| 2-33 | Ge₂₄Sn₅Te₂₈Sb₃₆Bi₂C₅ | 200 nm | 310° C. |
| 2-34 | Ge₃₀Te₃₀Sb₄₀ | 6 nm | 325° C. |
| 2-35 | Ge₃₀Te₃₀Sb₄₀ | 10 nm | 320° C. |
| 2-36 | Ge₃₀Te₃₀Sb₄₀ | 50 nm | 320° C. |
| 2-37 | Ge₃₀Te₃₀Sb₄₀ | 100 nm | 315° C. |
| 2-38 | Ge₃₀Te₃₀Sb₄₀ | 300 nm | 310° C. |

These results show that Samples 2-3 to 2-5, 2-9, 2-10, and Samples 2-34 to 2-38, each having a composition within a region defined by point (a) (35, 35, 30), point (b) (32.5, 27.5, 40), point (c) (25, 25, 50), and point (d) (27.5, 32.5, 40) and including lines from point (a) to point (b), from point (b) to point (c), from point (c) to point (d), and from point (d) to point (a), respectively, when coordinates (Ge, Te, Sb)=(x, y, z) are plotted on the triangular coordinate system of FIG. 1, satisfied the condition of the crystallization temperature of about 300° C. or higher (specifically, the crystallization temperature of 290° C. or higher), and thus were highly stable in the amorphous phase. In contrast, in Samples 2-1,2-2, 2-6 to 2-8, 2-11, and 2-12, each having a composition outside the region defined by point (a), point (b), point (c), and point (d), the crystallization temperatures were lower than 290° C., and thus the stability of the amorphous phase was not high enough.

Furthermore, in all of Samples 2-13, 2-14, 2-16, and 2-17, each being obtained by substituting a part of Sb in the composition of Ge₃₀Te₃₀Sb₄₀ by 5 atom % or less of Bi or In, the crystallization temperatures were 290° C. or higher, and thus the stability of the amorphous phase was high. In contrast, in Sample 2-15 obtained by substituting a part of Sb in the composition of Ge₃₀Te₃₀Sb₄₀ by more than 5 atom % of Bi, the crystallization temperature dropped to 275° C., which means that Sample 2-15 could not achieve the crystallization temperature of 290° C. or higher.

Furthermore, it was found that in both of Samples 2-18 and 2-19, each being obtained by substituting a part of Ge in the composition of Ge₃₀Te₃₀Sb₄₀ by 10 atom % or less of Sn, the crystallization temperatures were 300° C. or higher, and thus the stability of the amorphous phase was extremely high. In contrast, in Sample 2-20 obtained by substituting a part of Ge in the composition of Ge₃₀Te₃₀Sb₄₀ by more than 10 atom % of Sn, the crystallization temperature dropped to 285° C., which means that Sample 2-20 could not achieve the crystallization temperature of 290° C. or higher.

It was found that in all of Samples 2-21 to 2-28, each being obtained by adding 10 atom % or less of at least one element selected from Ga, Ag, Mn, Zn, C, Si, and N to the base composition of Ge₃₀Te₃₀Sb₄₀, the crystallization temperatures were 300° C. or higher, and thus the stability of the amorphous phase was extremely high.

It was found that in all of Samples 2-29 to 2-33, each being obtained by substituting a part of Sb in the composition of the recording layer by 5 atom % or less of Bi and/or In, and/or substituting a part of Ge in the composition of the recording layer by 10 atom % or less of Sn, and/or adding 10 atom % or less of C to the composition of the recording layer, the crystallization temperatures were 290° C. or higher, and thus the stability of the amorphous phase was high.

Herein, Samples 2-36, 2-37, and 2-38 having the composition of Ge₃₀Te₃₀Sb₄₀ and thicknesses of 50 nm, 100 nm, and 300 nm, respectively, could achieve the crystallization temperatures of 300° C. or higher. These results show that the materials for the recording layer of the present invention having compositions within the specified range can achieve high crystallization temperatures, when the thickness of the resulting recording layer is within the range of 5 nm to 300 nm that is preferable for the electrical information recording medium.

Furthermore, it was found that in Samples 2-34 and 2-35 having the composition of Ge₃₀Te₃₀Sb₄₀ and thicknesses of 6 nm and 10 nm, respectively, the crystallization temperatures were as high as 300° C. or higher. These results show that the materials having compositions around Ge₃₀Te₃₀Sb₄₀ can achieve very high crystallization temperatures of 300° C. or higher, when their thicknesses are within the preferable range of about 6 nm to 10 nm for the use in the optical information recording medium, and thus they have very high performance of long-term information storage, and can be used in high temperature environments.

### Example 3

In Example 3, the electrical information recording medium 1 of FIG. 2 was produced, and its phase change by application of electric current was observed.

As the substrate 8, a Si substrate, with the surface thereof being subjected to a nitriding treatment, was prepared. On this Si substrate, a layer made of TiW and having an area of 6 μm×6 μm and a thickness of 200 nm was formed as the lower electrode 9 by sputtering. On this lower electrode 9, a layer made of (SiO₂)₂₅(In₂O₃)₅₀(ZrO₂)₂₅ and having an area of 4.5 μm×5 μm and a thickness of 3 nm was formed as the first interface layer 11 by sputtering. On this first interface layer 11, a layer made of Ge₃₀Te₃₀Sb₄₀ with a crystallization temperature of 315° C. and having an area of 5 μm×5 μm and a thickness of 200 nm was formed as the recording layer 13 by sputtering. On this recording layer 13, a layer made of (SiO₂)₂₅(In₂O₃)₅₀(ZrO₂)₂₅ and having an area of 4.5 μm×5 μm and a thickness of 3 nm was formed as the second interface layer 12 by sputtering. Finally, on the second interface layer 12, a layer made of amorphous Si and having an area of 5 μm×5 μm and a thickness of 200 nm was formed as the upper electrode 10 by plasma CVD (at a substrate temperature of 250° C.). The electrical information recording medium 1 of Example 3 was obtained in this manner.

Then, an Au lead was bonded to the lower electrode 9 and the upper electrode 10, and the electrical information recording/reproducing apparatus 7 was connected to the electrical information recording medium 1 via the application units 2. With this electrical information recording/reproducing apparatus 7, the pulse power supply 5 was connected between the lower electrode 9 and the upper electrode 10 via the switch 4. Furthermore, the change in resistance caused by the phase change of the recording layer 13 was detected by the resistance measurement device 3 connected between the lower electrode 9 and the upper electrode 10 via the switch 6.

The recording layer 13 was in the amorphous phase in its initial state, and was not crystallized, although the upper electrode 10 was formed by plasma CVD. When the recording layer 13 was in this state, a current pulse of I_{c}=8 mA and t_{c}=50 ns in the recording waveform 23 shown in FIG. 5 was applied between the lower electrode 9 and the upper electrode 10. As a result, the recording layer 13 was transformed from the amorphous phase into the crystalline phase. Furthermore, when the recording layer 13 was in the crystalline phase, a current pulse of Iₐ=15 mA and t_{c}=10 ns in the erasing waveform 24 shown in FIG. 5 was applied between the lower electrode 9 and the upper electrode 10. As a result, the recording layer 13 was transformed from the crystalline phase into the amorphous phase.

In order to ascertain the effects of the interface layers, another electrical information recording medium 1 including neither the first interface layer 11 nor the second interface layer 12 was produced. This electrical information recording medium 1 was produced in the same manner as the electrical information recording medium 1 of Example 3 above except that the first interface layer 11 and the second interface layer 12 were not provided therein. The number of repeated rewritings of the electrical information recording medium 1 was measured. As a result, it was found that in the sample of Example 3 including the first interface layer 11 and the second interface layer 12, the number of repeated rewritings was at least 10 times greater than the sample including no interface layer. This is because the first interface layer 11 and the second interface layer 12 reduce the mass transfer from the lower electrode 9 and the upper electrode 10 to the recording layer 13.

### Example 4

In Example 4, the electrical information recording medium 101 of FIG. 6 was produced, and its phase change by application of electric current was observed.

As the substrate 108, a Si substrate, with the surface thereof being subjected to a nitriding treatment, was prepared. On this Si substrate, a layer made of TiW and having an area of 6 μm×6 μm and a thickness of 200 nm was formed as the lower electrode 109 by sputtering. On this lower electrode 109, a layer made of (SiO₂)₂₅(In₂O₃)₅₀(ZrO₂)₂₅ and having an area of 4.5 μm×5 μm and a thickness of 1 nm was formed as the first interface layer 111 by sputtering. On this first interface layer 111, a layer made of Ge₃₀Te₃₀Sb₄₀ with a crystallization temperature of 315° C. and having an area of 5 μm×5 μm and a thickness of 200 nm was formed as the recording layer 113 by sputtering. A layer made of amorphous Si and having an area of 6 μm×6 μm and a thickness of 200 nm further was formed as an intermediate electrode by plasma CVD (at a substrate temperature of 250° C.). On this intermediate electrode, a layer made of Ge₂Sb₂Te₅ with a crystallization temperature of 180° C. and having an area of 5 μm×5 μm and a thickness of 200 nm was formed as the second recording layer 114 by sputtering. On this second recording layer 114, a layer made of (SiO₂)₂₅(In₂O₃)₅₀(ZrO₂)₂₅ and having an area of 4.5 μm×5 μm and a thickness of 5 nm was formed as the second interface layer 112 by sputtering. Finally, on the second interface layer 112, a layer made of TiW and having an area of 5 μm×5 μm and a thickness of 200 nm was formed as the upper electrode 110 by sputtering. Herein, since the Ge2Sb2Te5 composition with a low crystallization temperature of 180° C. was used for the second recording layer 114, the second interface layer 112 and the upper electrode 110, which were to be formed after the formation of the second recording layer 114, were formed by sputtering, in which the substrate temperature increases to no more than about 70° C. during the deposition (film formation).

Then, an Au lead was bonded to the lower electrode 109 and the upper electrode 110, and the electrical information recording/reproducing apparatus 107 was connected to the electrical information recording medium 101 via the application units 102. With this electrical information recording/reproducing apparatus 107, the pulse power supply 105 was connected between the lower electrode 109 and the upper electrode 110 via the switch 104. Furthermore, the change in resistance caused by the phase change of the first recording layer 113 and the second recording layer 114 was detected by the resistance measurement device 103 connected between the lower electrode 109 and the upper electrode 110 via the switch 106.

The recording layer 113 and the second recording layer 114 were in the amorphous phase in their initial state, and the first recording layer 113 was not crystallized, although the intermediate electrode was formed by plasma CVD. The second recording layer 114 also was not crystallized because the second interface layer 112 and the upper electrode 110 were formed by sputtering and thus the substrate temperature increased to no more than about 70° C. When the first and second recording layers 113 and 114 were in this state, a current pulse of I_{c1}=13 mA and t_{c1}=50 ns in the recording waveform 115 shown in FIG. 7A was applied between the lower electrode 109 and the upper electrode 110. As a result, the first recording layer 113 and the second recording layer 114 were transformed from the amorphous phase into the crystalline phase. Furthermore, when the first recording layer 113 and the second recording layer 114 were in the amorphous phase, a current pulse of I_{c2}=5 mA and t_{c2}=30 ns in the recording waveform 116 shown in FIG. 7A was applied between the lower electrode 109 and the upper electrode 110. As a result, the second recording layer 114 was transformed from the amorphous phase into the crystalline phase.

When the first recording layer 113 and the second recording layer 114 were in the crystalline phase, a current pulse of Iₐ₁=25 mA, I_{c2}=5 mA, and t_{c2}=30 ns in the erasing waveform 117 shown in FIG. 7B was applied between the lower electrode 109 and the upper electrode 110. As a result, the first recording layer 113 was transformed from the crystalline phase into the amorphous phase. Furthermore, when the first recording layer 113 and the second recording layer 114 were in the crystalline phase, a current pulse of Iₐ₂=10 mA and tₐ₂=10 ns in the erasing waveform 118 shown in FIG. 7B was applied between the lower electrode 109 and the upper electrode 110. As a result, the second recording layer 114 was transformed from the crystalline phase into the amorphous phase. Furthermore, when the first recording layer 113 and the second recording layer 114 were in the crystalline phase, a current pulse of Iₐ₁=25 mA and tₐ₁=10 ns in the erasing waveform 119 shown in FIG. 7B was applied between the lower electrode 109 and the upper electrode 110. As a result, the first recording layer 113 and the second recording layer 114 were transformed from the crystalline phase into the amorphous phase.

These results confirmed that with the electrical information recording medium 101 including two recording layers, four different states, that is, binary information signals can be recorded/erased at a time.

### Example 5

For each of the recording layer 13 of Example 3 and the recording layer 113 of Example 4, when the material X having a composition within a region defined by point (a) (35, 35, 30), point (b) (32.5, 27.5, 40), point (c) (25, 25, 50), and point (d) (27.5, 32.5, 40) and including lines from point (a) to point (b), from point (b) to point (c), from point (c) to point (d), and from point (d) to point (a), respectively, when coordinates (Ge, Te, Sb)=(x, y, z) are plotted on the triangular coordinate system shown in FIG. 1, was used, the same results as in Example 3 and Example 4 were obtained. In this case, particularly when the material represented by (Ge_{0.5}Te_{0.5})₁₀₀₋ₐ₁Sbₐ₁(atom %), where a1 satisfies 30≦a1≦50, was used, the resulting recording layer could achieve satisfactory levels in both the crystallization temperature and the crystallization rate, and therefore the characteristics of the electrical information recording medium 1 and the electrical information recording medium 101 could be improved further.

### Example 6

For each of the recording layer 13 of Example 3 and the recording layer 113 of Example 4, when a part of Sb in the material X used in Example 5 was substituted by M1, where M1 is at least one element selected from Bi and In, and a M1 content in the material X was 5 atom % or less of the total material X, the resulting recording layer could achieve satisfactory levels in both the crystallization temperature and the crystallization rate, and therefore the characteristics of the electrical information recording medium 1 and the electrical information recording medium 101 could be improved further. When M1 is Bi, the crystallization rate of the recording layer was increased. Therefore, I_{c} and/or t_{c} of the current pulse required for the crystallization of the recording layer 13 of Example 3 could be reduced. When M1 is In, the stability of the amorphous phase of the recording layer was enhanced. Therefore, I_{c} and/or t_{c} of the current pulse required for the crystallization of the recording layer 13 of Example 3 needed to be increased.

Furthermore, for each of the recording layer 13 of Example 3 and the recording layer 113 of Example 4, when a part of Ge in the material X used in Example 5 was substituted by Sn and a Sn content in the material X was 10 atom % or less of the total material X, the resulting recording layer could increase the crystallization rate, and therefore the characteristics of the electrical information recording medium 1 and the electrical information recording medium 101 could be improved further. The crystallization rate could be increased by substituting a part of Ge by Sn. Therefore, I_{c} and/or t_{c} of the current pulse required for the crystallization of the recording layer 13 of Example 3 could be reduced.

Furthermore, for each of the recording layer 13 of Example 3 and the recording layer 113 of Example 4, when at least one element selected from Ga, Ag, Mn, Zn, C, Si, and N was further added to the recording layer so that the recording layer had a composition containing 10 atom % or less of these elements, the resulting recording layer could have an adjusted crystallization temperature and specific resistance, and therefore the characteristics of the electrical information recording medium 1 and the electrical information recording medium 101 could be improved further.

### Example 7

For each of the recording layer 13 of Example 3 and the recording layer 113 of Example 4, when the thickness in the range of 50 nm to 300 nm was selected for the recording layer, the same results as in Example 3 and Example 4 were obtained.

Furthermore, for each of the first interface layer 11 and the second interface layer 12 of Example 3, and the first interface layer 111 and the second interface layer 112 of Example 4, when the thickness in the range of 1 nm to 5 nm was selected for the interface layer, the same results as in Example 3 and Example 4 were obtained. When a material containing O, at least one element selected from Zr, Hf, Y, and Si, and at least one element selected from Ga, In, and Cr was used as the material for the interface layer, the same results as in Example 3 and Example 4 were obtained.

### INDUSTRIAL APPLICABILITY

The information recording medium according to the present invention has the property of being able to store recorded information for a long time (non-volatility) and is useful as an electrical non-volatile memory or the like. This information recording medium also can be used for applications such as high-density rewritable optical disks (for example, a Blu-ray Disc Rewritable (BD-RE), a DVD-RAM, a DVD-RAM, a DVD-RW, etc.).

1. An information recording medium on which information can be recorded by application of electrical energy, the medium comprising:
a recording layer whose phase can be changed by application of electrical energy;
an interface layer disposed in contact with at least one surface of the recording layer; and
an electrode disposed on a side opposite to the recording layer with respect to the interface layer, wherein
the recording layer contains, as a main component, a material consisting of Ge, Te, and Sb,
the material has a composition within a region defined by point (a) (35, 35, 30), point (b) (32.5, 27.5, 40), point (c) (25, 25, 50), and point (d) (27.5, 32.5, 40) and including lines from point (a) to point (b), from point (b) to point (c), from point (c) to point (d), and from point (d) to point (a), respectively, when coordinates (Ge, Te, Sb)=(x, y, z) are plotted on a triangular coordinate system shown in FIG. 1, and
the interface layer contains at least one compound selected from an oxide, a nitride, a carbide, a sulfide, and a fluoride.

2. The information recording medium according to claim 1, wherein the material has a composition represented by the following formula:
(Ge_{0.5}Te_{0.5})₁₀₀₋ₐ₁Sbₐ₁(atom %) (1)
where a1 satisfies 30≦a1≦50.

3. The information recording medium according to claim 1, wherein
a part of Sb in the material is substituted by M1, where M1 is at least one element selected from Bi and In, and
a M1 content in the material is 5 atom % or less of the total material.

4. The information recording medium according to claim 1, wherein
a part of Ge in the material is substituted by Sn, and
a Sn content in the material is 10 atom % or less of the total material.

5. The information recording medium according to claim 1, wherein the recording layer further contains at least one element selected from Ga, Ag, Mn, Zn, C, Si, and N.

6. The information recording medium according to claim 1, wherein the recording layer has a thickness in a range of 50 nm to 300 nm.

7. The information recording medium according to claim 1, comprising:
n information layers, where n is an integer of 2 or more, and
at least one of the n information layers includes the recording layer.

8. (canceled)

9. The information recording medium according to claim 1, wherein the interface layer contains 0, at least one element selected from Zr, Hf, Y, and Si, and at least one element selected from Ga, In, and Cr.

10. The information recording medium according to claim 1, wherein the interface layer has a thickness in a range of 1 nm to 5 nm.

11. A method of manufacturing an information recording medium, the method comprising the steps of:
forming a recording layer;
forming an interface layer; and
forming an electrode, wherein
the recording layer formed in the step of forming the recording layer contains, as a main component, a material consisting of Ge, Te, and Sb, and
the material has a composition within a region defined by point (a) (35, 35, 30), point (b) (32.5, 27.5, 40), point (c) (25, 25, 50), and point (d) (27.5, 32.5, 40) and including lines from point (a) to point (b), from point (b) to point (c), from point (c) to point (d), and from point (d) to point (a), respectively, when coordinates (Ge, Te, Sb)=(x, y, z) are plotted on a triangular coordinate system shown in FIG. 1.

12. The method of manufacturing an information recording medium according to claim 11, wherein the material has a composition represented by the following formula:
(Ge_{0.5}Te_{0.5})₁₀₀₋ₐ₂Sbₐ2 (atom %) (2)
where a2 satisfies 30≦a2≦50.

13. The method of manufacturing an information recording medium according to claim 11, wherein
a part of Sb in the material is substituted by M1, where M1 is at least one element selected from Bi and In, and
a M1 content in the material is 5 atom % or less of the total material.

14. The method of manufacturing an information recording medium according to claim 11, wherein
a part of Ge in the material is substituted by Sn, and
a Sn content in the material is 10 atom % or less of the total material.

15. The method of manufacturing an information recording medium according to claim 11, wherein the recording layer formed in the step of forming the recording layer further contains at least one element selected from Ga, Ag, Mn, Zn, C, Si, and N.

16. A sputtering target used in a step of forming a recording layer in a method of manufacturing an information recording medium according to claim 11, wherein the sputtering target has a composition represented by the following formula:
(Ge_{0.5}Te_{0.5})₁₀₀₋ₐ₃Sbₐ₃ (atom %) (3)
where a3 satisfies 28≦a3≦48.
